(19) United States
(12) Patent Application Publication
(10) Pub. No.: US 2026/0239714 A1
(43) Pub. Date: Aug. 13, 2026

(54) TRANSISTORS INCLUDING ANNULAR GATES, AND RELATED MICROELECTRONIC DEVICES AND ELECTRONIC SYSTEMS

(71) Applicant: Micron Technology, Inc., Boise, ID (US)

(72) Inventors: Martin W. Popp, Meridian, ID (US); Srinivas Pulugurtha, Boise, ID (US); Yui Shimizu, Santa Clara, CA (US)

(21) Appl. No.: 19/450,565

(22) Filed: Jan. 15, 2026

Related U.S. Application Data
(60) Provisional application No. 63/758,254, filed on Feb. 13, 2025.

(51) Int. Cl. H10D 64/27

(52) U.S. Cl. CPC H10D 64/519

(57) ABSTRACT

A transistor includes a drain, a channel substantially horizontally circumscribing the drain, a source at least partially horizontally circumscribing the channel, a gate vertically overlying and substantially covering a horizontal area of the channel, and a gate dielectric material vertically interposed between and horizontally overlapping the gate and the channel. The gate includes portions partially horizontally overlapping the source and the drain. Microelectronic devices and electronic systems are also described.

### CROSS-REFERENCE TO RELATED APPLICATIONS

This application claims the benefit under 35 U.S.C. § 119(e) of U.S. Provisional Patent Application Ser. No. 63/758,254, filed Feb. 13, 2025, the disclosure of which is hereby incorporated herein in its entirety by this reference.

### TECHNICAL FIELD

This disclosure, in various embodiments, relates generally to the field of microelectronic device design. More specifically, this disclosure relates to transistors including annular gates, and to related microelectronic devices and electronic systems.

### BACKGROUND

Microelectronic device designers often desire to increase the level of integration or density of features within a microelectronic device by reducing the dimensions of the individual features and by reducing the separation distance between neighboring features. In addition, microelectronic device designers often desire to design architectures that are not only compact, but offer performance advantages, as well as simplified designs.

One example of a microelectronic device is a memory device. Memory devices are generally provided as internal integrated circuits in computers or other electronic devices. There are many types of memory including, but not limited to, random-access memory (RAM), read only memory (ROM), static random access memory (SRAM), dynamic random access memory (DRAM), synchronous dynamic random access memory (SDRAM), Flash memory, and resistance variable memory. Challenges related to memory device fabrication include decreasing the size of a memory device and increasing the storage density of a memory device.

### BRIEF DESCRIPTION OF THE DRAWINGS

FIG. 1A is a simplified, top-down view of a microelectronic device structure, in accordance with a first embodiment of the disclosure.

FIG. 1B is a simplified, vertical cross-sectional view of the microelectronic device structure of FIG. 1A about line A-A shown in FIG. 1A.

FIG. 2 is a simplified, top-down view of a microelectronic device structure, in accordance with a second embodiment of the disclosure.

FIG. 3A is a simplified, top-down view of a microelectronic device structure, in accordance with a third embodiment of the disclosure.

FIG. 3B is a magnified, top-down view of a portion of the microelectronic device structure shown in FIG. 3A.

FIG. 4 is a simplified, top-down view of a microelectronic device structure, in accordance with a fourth embodiment of the disclosure.

FIG. 5 is a simplified, top-down view of a microelectronic device structure, in accordance with a fifth embodiment of the disclosure.

FIG. 6 is a simplified, top-down view of a microelectronic device structure, in accordance with a sixth embodiment of the disclosure.

FIG. 7 is a simplified, top-down view of a microelectronic device structure, in accordance with an eighth embodiment of the disclosure.

FIG. 8 is a simplified, top-down view of a microelectronic device structure, in accordance with a ninth embodiment of the disclosure.

FIG. 9 is a simplified diagram of an inverter, in accordance with embodiments of the disclosure.

FIG. 10 is a functional block diagram of a memory device, in accordance with embodiments of the disclosure.

FIG. 11 is a schematic block diagram of an electronic system, in accordance with embodiments of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. In addition, the description provided below does not form a complete process flow for manufacturing a microelectronic device (e.g., a memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, unless otherwise stated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessarily limited to memory functionality. Stated another way, and by way of non-limiting example only, the term “memory device” includes not only conventional memory (e.g., conventional non-volatile memory; conventional volatile memory), but also includes an application specific integrated circuit (ASIC) (e.g., a system on a chip (SoC)), a microelectronic device combining logic and memory, and a graphics processing unit (GPU) incorporating memory.

As used herein, the terms “configured” and “configuration” refers to a size, a shape, a material composition, a material distribution, orientation, and arrangement of at least one feature (e.g., one or more of at least one structure, at least one material, at least one region, at least one device) facilitating use of the at least one feature in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the drawings, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., structures, materials, regions, devices) described as “neighboring” one another means and includes features of the disclosed identity (or identities) that are located most proximate (e.g., closest to) one another. Additional features (e.g., additional regions, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the drawings. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the term “may” with respect to a material, structure, feature, or method act indicates that such is contemplated for use in implementation of an embodiment of the disclosure, and such term is used in preference to the more restrictive term “is” so as to avoid any implication that other compatible materials, structures, features, and methods usable in combination therewith should or must be excluded.

As used herein, the singular forms “a,” “an,” and “the” are intended to include the plural forms as well, unless the context clearly indicates otherwise.

As used herein, “and/or” includes any and all combinations of one or more of the associated listed items.

As used herein, the phrase “coupled to” refers to structures operatively connected with each other, such as electrically connected through a direct Ohmic connection or through an indirect connection (e.g., by way of another structure).

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, “mathematically similar” in reference to two geometric figures means and includes two figures with the same geometric shape but different geometric sizes.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively doped semiconductor material (e.g., conductively doped polysilicon, conductively doped germanium (Ge), conductively doped silicon germanium (SiGe)). In addition, a “conductive structure” means and includes a structure formed of and including conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), at least one dielectric oxycarbide material (e.g., silicon oxycarbide (SiOₓC_{y})), at least one hydrogenated dielectric oxycarbide material (e.g., hydrogenated silicon oxycarbide (SiCₓO_{y}H_{z})), and at least one dielectric carboxynitride material (e.g., a silicon carboxynitride (SiOₓC_{z}N_{y})). In addition, an “insulative structure” means and includes a structure formed of and including insulative material.

As used herein, the term “semiconductor material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials.

Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{y}, SiCₓO_{y}H_{z}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including insulative material.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

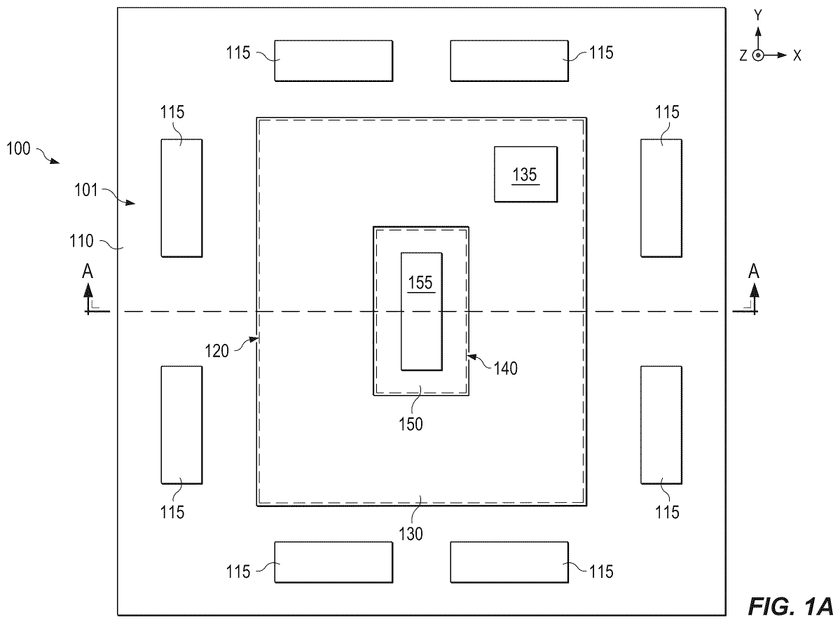

FIG. 1A is simplified, top-down view of a microelectronic device structure 100 for a microelectronic device (e.g., a memory device), in accordance with embodiments (e.g., a first embodiment) of the disclosure. FIG. 1B is a simplified, vertical cross-sectional view of the microelectronic device structure 100 of FIG. 1A about line A-A show in FIG. 1A. With the description provided below, it will be readily apparent to one of ordinary skill in the art that the embodiments described herein may be used in various devices.

Referring collectively to FIGS. 1A and 1B, the microelectronic device structure 100 may include a transistor 101 having a source 110, a drain 150, and a gate 130 between and partially horizontally overlapping the source 110 and the drain 150. One or more source contacts 115 may vertically overlie and be coupled to the source 110 of the transistor 101. Similarly, one or more drain contacts 155 may vertically overlie and be coupled to the drain 150 of the transistor 101, and one or more gate contacts 135 may vertically overlie and be coupled to the gate 130 of the transistor 101. The transistor 101 further includes a channel 160 vertically below the gate 130, and horizontally extending between the source 110 and the drain 150. The transistor 101 also includes gate dielectric material 170 vertically interposed between and horizontally overlapping the gate 130 and the channel 160. As shown in FIG. 1B, in some embodiments, the gate dielectric material 170 horizontally extends continuously over upper surfaces of the source 110, the drain 150, and the channel 160 of the transistor 101.

As described in further detail below, the transistor 101 has a geometric configuration facilitating reduced capacitive load and enhanced performance relative to conventional transistor configurations. In some embodiments, the transistor 101 has a generally annular shape (e.g., a rectangular annular shape, such as a square annular shape) for some features thereof, such as the source 110, the gate 130, and the channel 160. For example, the source 110 substantially horizontally circumscribes each of the gate 130 and the channel 160, and the gate 130 and the channel 160 each substantially horizontally circumscribe the drain 150. Such a configuration effectively reduces drain width for a given source width, thereby reducing overlap capacitance and gate area. Gate length may be relatively uniform (as compared to conventional configurations) to ensure consistent performance, with the gate 130 partially horizontally overlapping and extending between each of the source 110 and the drain 150. Perimeters of the source 110 and the drain 150 may be substantially mathematically similar, ensuring efficient electron flow and reduced parasitic capacitance. The configuration of the transistor 101 facilitates relatively higher input/output (I/O) speeds and relatively lower power consumption as compared to conventional transistor configurations, making the transistor 101 particularly advantageous for incorporation and use in microelectronic devices (e.g., memory devices, such as volatile memory devices or non-volatile memory devices) where minimizing capacitive load is critical for achieving higher switching frequencies and improved power efficiency.

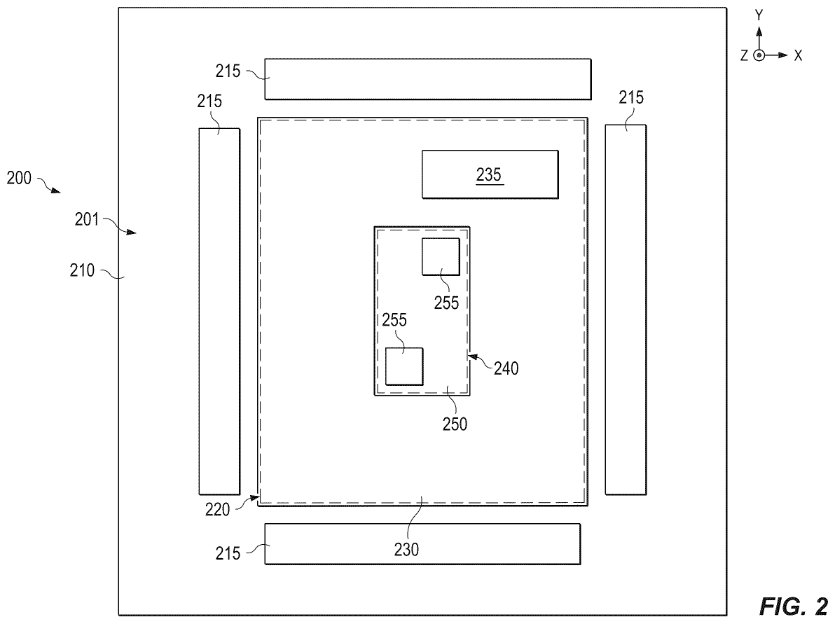

The source 110 of the transistor 101 may have an internal source perimeter 111 (e.g., an internal horizontal boundary) that substantially horizontally circumscribes (e.g., in the X-direction, in the Y-direction) the channel 160 (and, hence, the drain 150) of the transistor 101. In some embodiments, the internal source perimeter 111 is directly horizontally adjacent to an external channel perimeter of the channel 160. A total horizontal dimension (e.g., width in the X-direction, length in the Y-direction) of the source 110 from the internal source perimeter 111 to an opposing side of the source 110 may be within a range of from about 20 nanometers (nm) to about 500 nm, such as from about 50 nm to about 200 nm, or from about 100 nm to about 150 nm. A geometric configuration (e.g., shape, size) of the source 110, including a geometric configuration of the internal source perimeter 111 thereof, may be influenced by geometric configurations of other features of the transistor 101 (e.g., the drain 150, the channel 160, the gate 130). As collectively shown in FIGS. 1A and 1B, in some embodiments, the internal source perimeter 111 has a rectangular horizontal shape influenced, at least in part, by complementary horizontal cross-sectional shapes of the drain 150, the channel 160, and the gate 130. In additional embodiments, such as those described in further detail below with reference to FIGS. 3A through 6, the source 110 may have a different geometric configuration (e.g., a different horizontal shape, such as a square horizontal shape, a pentagonal horizontal shape, a hexagonal horizontal shape, an octagonal horizontal shape, a closed-curve horizontal shape). The source 110 may have a desirable horizontal area, such as a horizontal area within a range from about 1000 nm² to about 20000 nm², from about 2000 nm² to about 10000 nm², or from about 30000 nm² to about 5000 nm².

The drain 150 of the transistor 101 may have an external drain perimeter 159 (e.g., an external horizontal boundary) substantially horizontally circumscribed by (e.g., in the X-direction, in the Y-direction) the channel 160 (and, hence, the source 110) of the transistor 101. In some embodiments, the external drain perimeter 159 is directly horizontally adjacent to an internal horizontal perimeter of the channel 160. A total horizontal dimension (e.g., width in the X-direction, length in the Y-direction) of the drain 150 between opposing portions of the external drain perimeter 159 may be within a range of from about 20 nm to about 500 nm, such as from about 50 nm to about 200 nm, or from about 100 nm to about 150 nm. A geometric configuration (e.g., shape, size) of the drain 150, including a geometric configuration of the external drain perimeter 159 thereof, may influence and/or be influenced by geometric configurations of other features of the transistor 101 (e.g., the source 110, the channel 160, the gate 130). As shown collectively shown in FIGS. 1A and 1B, in some embodiments, the external drain perimeter 159 has a rectangular horizontal shape. In additional embodiments, such as those described in further detail below with reference to FIGS. 3A through 6, the drain 150 may have a different geometric configuration (e.g., a different horizontal shape, such as a square horizontal shape, a pentagonal horizontal shape, hexagonal horizontal shape, an octagonal horizontal shape, a closed-curve horizontal shape). In some embodiments, the horizontal shape of the external drain perimeter 159 is substantially the same as (e.g., substantially mathematically similar to) the horizontal shape of the internal source perimeter 111. A ratio of a size of the external drain perimeter 159 of the drain 150 to the internal source perimeter 111 to a size of the source 110 may be within a range from about 0.3 to about 1.0, such as from about 0.4 to about 0.8, or from about 0.5 to about 0.6. The drain 150 may have a desirable horizontal area, such as a horizontal area within a range from about 500 nm² to about 50000 nm², such as from about 1000 nm² to about 4000 nm², or from about 2000 nm² to about 3000 nm².

Still referring collectively to FIGS. 1A and 1B, the channel 160 of the transistor 101 may be horizontally interposed (e.g., in the X-direction and in the Y-direction) between the internal source perimeter 111 of the source 110 and the external drain perimeter 159 of the drain 150. The channel 160 substantially horizontally circumscribes (e.g., in the X-direction, in the Y-direction) the external drain perimeter 159 of the drain 150 of the transistor 101. In some embodiments, the channel 160 horizontally extends (e.g., in the X-direction, in the Y-direction) from and between opposing portions of the internal source perimeter 111 of the source 110 and the external drain perimeter 159 of the drain 150. A total horizontal dimension between opposing portions of the internal source perimeter 111 of the source 110 and the external drain perimeter 159 of the drain 150 may be within a range from about 5 nm to about 100 nm, such as from about 10 nm to about 50 nm, or from about 15 nm to 20 nm. The channel 160 may have a substantially uniform horizontal dimension, or may have variable horizontal dimensions. A geometric configuration (e.g., shape, size) of the channel 160 may influence and/or be influenced by geometric configurations of other features of the transistor 101 (e.g., the source 110, the drain 150, the gate 130). In some embodiments, the channel 160 has an annular horizontal cross-sectional shape (e.g., a rectangular annular horizontal cross-sectional shape) influenced by (e.g., complementary to) the horizonal shapes (e.g., rectangular horizontal shapes) of the internal source perimeter 111 of the source 110 and the external drain perimeter 159 of the drain 150.

The source 110, the drain 150, and the channel 160 may respectively be formed from and constitute portions of a relatively larger semiconductor base structure (e.g., semiconductor substrate). The source 110 and the drain 150 may respectively comprise conductively doped semiconductor material, and may have the same conductive type (e.g., N-type, P-type) as one another. The channel 160 may comprise undoped semiconductor material, or conductively doped semiconductor material having a different conductivity type than that of the source 110 and the drain 150. As shown in FIG. 1B, upper boundaries (e.g., upper surfaces) of the source 110, the drain 150, and the channel 160 may be substantially coplanar with one another.

The gate dielectric material 170 of the transistor 101 may be vertically interposed (e.g., in the Z-direction) between the channel 160 and the gate 130. The gate dielectric material 170 substantially covers each of an upper boundary (e.g., upper surface) of the channel 160 and a lower boundary (e.g., a lower surface) of the gate 130. The gate dielectric material 170 may at least horizontally extend from and between an outer gate perimeter 139 and an inner gate perimeter 131 of the gate 130. The gate dielectric material 170 may also at least partially cover upper boundaries (e.g., upper surfaces) of the source 110 and the drain 150. The gate dielectric material 170 may have a desired vertical thickness, such as a vertical thickness within a range of from about 0.5 nm to about 5 nm, or from about 1 nm to about 2 nm. The gate dielectric material 170 may have a substantially uniform vertical thickness, or may have variable vertical thicknesses. In some embodiments, the gate dielectric material 170 is formed of and includes dielectric oxide material (e.g., SiOₓ, such as SiO₂).

The gate 130 (e.g., gate electrode) of the transistor 101 is horizontally disposed between and partially horizontally overlaps each of the source 110 and the drain 150. The gate 130 vertically overlies the gate dielectric material 170 and substantially covers a horizonal area of the channel 160. Horizontal dimensions and a horizontal area of the gate 130 may be greater than corresponding horizontal dimensions and a horizontal area of the channel 160. The gate 130 may have portions that do not horizontally overlap either of the source 110 or the drain 150.

A geometric configuration (e.g., shape, size) of the gate 130 may influence and/or be influenced by geometric configurations of other features of the transistor 101 (e.g., the source 110, the drain 150, the channel 160). In some embodiments, the gate 130 has an annular horizontal cross-sectional shape (e.g., a rectangular annular horizontal cross-sectional shape) influenced by (e.g., complementary to) an annular horizontal cross-sectional shape (e.g., a rectangular annular horizontal cross-sectional shape) of the channel 160 and the horizonal shapes (e.g., rectangular horizontal shapes) of the internal source perimeter 111 of the source 110 and the external drain perimeter 159 of the drain 150. In some embodiments, a horizontal dimension of the gate 130 from a portion of the inner gate perimeter 131 thereof to an opposing portion of the outer gate perimeter 139 thereof is within a range of from about 5 nm to about 100 nm, such as from about 10 nm to about 50 nm, or from about 15 nm to about 20 nm. The gate 130 may have substantially uniform horizontal dimensions between the inner gate perimeter 131 and the outer gate perimeter 139 thereof, or may have variable horizontal dimensions between the inner gate perimeter 131 and the outer gate perimeter 139 thereof. If the gate 130 has variable horizontal dimensions, the gate 130 may have a maximum gate length and a minimum gate length between opposing portions of the inner gate perimeter 131 and the outer gate perimeter 139 thereof. The ratio of the maximum gate length of the gate 130 to the minimum gate length of the gate 130 may be within a range from about 1.5 to about 1, such as from about 1.4 to about 1.1, or from about 1.3 to about 1.2. In some embodiments, the gate 130 has a substantially uniform gate length between the inner gate perimeter 131 and the outer gate perimeter 139 thereof. Substantially uniform gate length of the gate 130 between the inner gate perimeter 131 and the outer gate perimeter 139 may facilitate efficient electron flow between the source 110 and the drain 150.

The gate 130 may include a source overlap region 120 that horizontally overlaps the source 110 by a source overlap distance D1. In addition, the gate 130 may include a drain overlap region 140 horizontally overlapping the drain 150 by a drain overlap distance D2. The source overlap distance D1 may be substantially equal to the drain overlap distance D2, or the source overlap distance D1 may be different than the drain overlap distance D2. A magnitude of the source overlap distance D1 may be a percentage of a corresponding horizontal dimension between the inner gate perimeter 131 and the outer gate perimeter 139 of the gate 130, such as from about 2.5% to about 15% of the horizontal dimension, from about 5% to about 10% of the horizontal dimension, or from about 7% to about 8% of the horizontal dimension. Similarly, a magnitude of the drain overlap distance D2 may be a percentage of a corresponding horizontal dimension between the inner gate perimeter 131 and the outer gate perimeter 139 of the gate 130, such as from about 2.5% to about 15% of the horizontal dimension, from about 5% to about 10% of the horizontal dimension, or from about 7% to about 8% of the horizontal dimension. A horizontal area of the source overlap region 120 may be less than a horizontal area of the drain overlap region 140. The ratio of the horizontal area of the source overlap region 120 to the horizontal area of the drain overlap region 140 may be within a range of from about 0.2 to about 0.95, such as from about 0.3 to about 0.8, or from about 0.4 to about 0.6.

A horizontal shape of the inner gate perimeter 131 of the gate 130 may be substantially mathematically similar to the horizontal shape of the external drain perimeter 159 of the drain 150. The horizontal shape of the inner gate perimeter 131 of the gate 130 may be substantially congruent to the horizontal shape of the external drain perimeter 159 of the drain 150. Similarly, the horizontal shape of the outer gate perimeter 139 of the gate 130 may be substantially mathematically similar to the horizontal shape of the internal source perimeter 111 of the source. The horizontal shape of the outer gate perimeter 139 of the gate 130 may be substantially congruent to the horizontal shape of the internal source perimeter 111 of the source 110.

Parasitic capacitance results from overlap of the gate 130 with the drain 150 of the transistor. The parasitic capacitance is linearly related to the area of the overlap, and accordingly, a reduction in the overlap area reduces the parasitic capacitance. The overlap arrangement illustrated in FIGS. 1A and 1B reduces parasitic capacitance of the drain 150, effectively increasing the speed of the transistor. The annular configuration of the gate 130 utilizes the entire external drain perimeter 159 of the drain 150, rather than just two sides (as used in many conventional transistor configurations), which reduces the area of the drain overlap region 140 for a constant source overlap region 120 area.

Still collectively referring to FIGS. 1A and 1B, source contact(s) 115 may be located at desired horizontal positions within a horizontal area of the source 110 of the transistor 101. In FIG. 1A, multiple source contacts 115 are positioned within a horizontal area of the source 110 (e.g., six (6) source contacts 115, with two (2) of the six (6) source contacts 115 horizontally neighboring each of four (4) side surfaces of the gate 130), and each of the source contacts 115 has a rectangular horizontal cross-sectional shape. However, the transistor 101 may employ different configurations (e.g., quantities, positions, orientations, shapes, sizes, materials) of the source contact(s) 115. Configurations (e.g., quantities, positions, orientations, shapes, sizes, material) of the source contacts 115 may at least partially depend on configurations (e.g., quantities, positions, orientations, shapes, sizes, material) of the other features (e.g., the source 110, the drain 150, the channel 160, the gate 130) of the transistor 101.

The source contact(s) 115 may respectively be formed of and include conductive material (e.g., one or more of a metal, an alloy, a conductive metal oxide, a conductive metal nitride, a conductive metal silicide, and a conductively doped semiconductor material). By way of non-limiting example, the source contact(s) 115 may respectively be formed of and include one or more of W, WN, Ni, Ta, TaN, TaSi, Pt, Cu, Ag, Au, Al, Mo, Ti, TiN, TiSi, TiSiN, TiAlN, MoN, Ir, IrOₓ, Ru, RuOₓ, and conductively doped silicon. The source contact(s) 115 may respectively vertically extend through the gate dielectric material 170 and to the source 110.

The source contact(s) 115 may individually be horizontally offset from a portion of the gate 130 most proximate thereto by a horizontal distance within a range of from about 20 nm to about 200 nm, such as from about 40 nm to about 150 nm, or from about 60 nm to about 100 nm. If multiple source contacts 115 are included, each of the source contacts 115 may be separated from the gate 130 by substantially the same horizontal distance, or at least one of the source contacts 115 may be separated from the gate 130 by a different horizontal distance than at least one other of the source contacts 115.

The drain contact(s) 155 may be located at desired horizontal positions within a horizontal area of the drain 150 of the transistor 101. In FIG. 1A, a single (e.g., only one) drain contact 155 is positioned at a horizontal center of the drain 150, and has a rectangular cross-sectional shape. However, the transistor 101 may employ different configurations (e.g., quantities, positions, orientations, shapes, sizes, materials) of the drain contact(s) 155. Configurations (e.g., quantities, positions, orientations, shapes, sizes, material) of the drain contact(s) 155 may at least partially depend on configurations (e.g., quantities, positions, orientations, shapes, sizes, material) of the other features (e.g., the source 110, the drain 150, the channel 160, the gate 130) of the transistor 101.

The drain contact(s) 155 may respectively be formed of and include conductive material (e.g., one or more of a metal, an alloy, a conductive metal oxide, a conductive metal nitride, a conductive metal silicide, and a conductively doped semiconductor material). By way of non-limiting example, the drain contact(s) 155 may respectively be formed of and include one or more of W, WN, Ni, Ta, TaN, TaSi, Pt, Cu, Ag, Au, Al, Mo, Ti, TiN, TiSi, TiSiN, TiAlN, MoN, Ir, IrOₓ, Ru, RuOₓ, and conductively doped silicon. The drain contact(s) 155 may respectively vertically extend through the gate dielectric material 170 and to the drain 150.

The drain contact(s) 155 may individually be horizontally offset from a portion of the gate 130 most proximate thereto by a horizontal distance within a range of from about 20 nm to about 200 nm, such as from about 40 nm to about 150 nm, or from about 60 nm to about 100 nm. If multiple drain contacts 155 are included, each of the drain contacts 155 may be separated from the gate 130 by substantially the same horizontal distance, or at least one of the drain contacts 155 may be separated from the gate 130 by a different horizontal distance than at least one other of the drain contacts 155.

The gate contact(s) 135 may be located at desired horizontal positions within a horizontal area of the gate 130 of the transistor 101. In FIG. 1A, a single (e.g., only one) gate contact 135 is horizontally positioned proximate a horizontal corner of the gate 130, and has a rectangular horizontal cross-sectional shape. However, the transistor 101 may employ different configurations (e.g., quantities, positions, orientations, shapes, sizes, materials) of the gate contact(s) 135. Configurations (e.g., quantities, positions, orientations, shapes, sizes, material) of the drain contact(s) 155 may at least partially depend on configurations (e.g., quantities, positions, orientations, shapes, sizes, material) of the other features (e.g., the source 110, the drain 150, the channel 160, the gate 130) of the transistor 101.

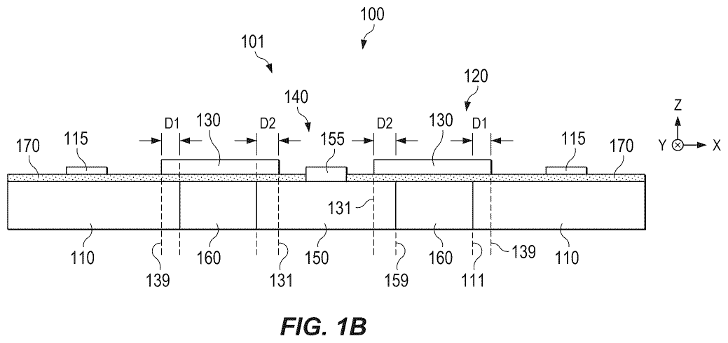

In additional embodiments, the microelectronic device structure 100 may be formed to have a different configuration than that previously described with reference to FIGS. 1A and 1B. The microelectronic device structure 100 may, for example, be formed to exhibit one of the configurations depicted in FIGS. 2 through 8 and described in further detail below. With the description provided below, it will be readily apparent to one of ordinary skill in the art that the structures and devices described herein may be included in relatively larger structures, devices, and systems.

Before referring to FIG. 2, it will be understood that throughout the FIGS. 2 through 9 and the associated description, features (e.g., regions, materials, structures, devices) functionally similar to previously described features (e.g., previously described materials, structures, devices) are referred to with similar reference numerals incremented by 100. To avoid repetition, not all features shown in FIGS. 2 through 9 are described in detail herein. Rather, unless described otherwise below, a feature in one or more of FIGS. 2 through 9 designated by a reference numeral that is a 100 increment of the reference numeral of a feature previously described with reference to one or more of FIGS. 1A and 1B will be understood to be substantially similar to and have substantially the same advantages as the previously described feature. In addition, unless described otherwise below, a feature in one or more of FIGS. 3 through 9 designated by a reference numeral that is a 100 increment of the reference numeral of a feature previously described with reference to a preceding one or more of FIGS. 2 through 8 will be understood to be substantially similar to and have substantially the same advantages as the previously described feature. As a non-limiting example, unless described otherwise below, features designated by the reference numerals 230, 330, 430, 530, 630, 730, 830, 930 in FIGS. 2 through 9, respectively, will be understood to respectively be substantially similar to and have substantially the same advantages as the gate 130 previously described herein with reference to FIGS. 1A and 1B. In addition, for clarity and ease of understanding the drawings and related description, some features (e.g., structures, materials, regions, devices) previously described with reference to one or more of FIGS. 1A and 1B are not depicted in FIGS. 2 through 9. However, unless described otherwise below, it will be understood that any features of the microelectronic device structure 100 previously described with reference to FIGS. 1A and 1B may be included in any of the different configurations described hereinbelow with reference to FIGS. 2 through 9. As a non-limiting example, features substantially similar to the gate dielectric material 170 previously described with reference to FIGS. 1A and 1B may be included in the different configurations described hereinbelow with reference to FIGS. 2 through 9.

FIG. 2 is a simplified, top-down view of a microelectronic device structure 200, in accordance with additional embodiments (e.g., a second embodiment) of the disclosure. The microelectronic device structure 200 may be similar to the microelectronic device structure 100 previously described with reference to FIGS. 1A and 1B, except that, for example, the microelectronic device structure 200 may exhibit different configurations of source contacts 215, drain contacts 255, and gate contact(s) 235 thereof.

As shown in FIG. 2, the microelectronic device structure 200 includes source contacts 215 that individually horizontally extend substantially completely across one of the horizontal boundaries of the gate 230. An individual source contact 215 may horizontally extend along the horizontal dimension of a linear portion of an internal source perimeter (corresponding to the internal source perimeter 111 (FIG. 1B)) of the transistor 201. The microelectronic device structure 200 is illustrated as having four (4) source contacts 215 (one for each of four (4) horizontal sides of the source perimeter 211), but a greater or lesser number of the source contacts 215 is possible. Each of the source contacts 215 may exhibit substantially a same horizontal area as each other of the source contacts 215, or at least one of the source contacts 215 may exhibit a different horizontal area than at least one other of the source contacts 215. In addition, as compared with the source contacts 115 (FIGS. 1A and 1B) of the microelectronic device structure 100 (FIGS. 1A and 1B), one or more (e.g., each) of the source contacts 215 may be relatively horizontally closer to the gate 230.

The microelectronic device structure 200 also includes drain contacts 255 respectively having a horizontal center horizontally offset from a horizontal center of drain 250 of the transistor 201. The microelectronic device structure 200 is illustrated as having two drain contacts 255, but a greater or lesser number of drain contacts 255 is possible. In some embodiments, the drain contacts 255 are horizontally offset from one another in each of the X-direction and the Y-direction. In additional embodiments, the drain contacts 255 may at least partially horizontally overlap one another in the X-direction or the Y-direction. As shown in FIG. 2, in some embodiments, horizontal centerlines of the drain contacts 255 in the X-direction may be offset from a horizontal centerline of the drain 250 in the X-direction, and horizontal centerlines of the drain contacts 255 in the Y-direction may be offset from a horizontal centerline of the drain 250 in the Y-direction. In additional embodiments, a horizontal centerline of at least one of the drain contacts 255 in the X-direction may be substantially aligned with a horizontal centerline of the drain 250 in the X-direction, and/or a horizontal centerline of at least one of the drain contacts 255 in the Y-direction may be substantially aligned with a horizontal centerline of the drain 250 in the Y-direction. The drain contacts 255 may be formed to have different horizontal cross-sectional shapes. As compared with the drain contact 155 (FIGS. 1A and 1B) of the microelectronic device structure 100 (FIGS. 1A and 1B), one or more of the drain contacts 255 may be relatively horizontally closer to the gate 230.

The microelectronic device structure 200 further includes at least one gate contact 235. The microelectronic device structure 200 is illustrated as having only one (1) gate contact 235, but a greater number of gate contacts 235 is possible. In some embodiments, the gate contact 235 is positioned at or proximate one of the horizontal corners of the gate 230. In additional embodiments, the gate contact 235 may be positioned at or proximate a different horizontal corner of the gate 230, or may be horizontally positioned more horizontally distal from horizontal corners of the gate 230 (e.g., relatively more horizontally centrally positioned along the gate 230). As compared with the gate contact 135 (FIGS. 1A and 1B) of the microelectronic device structure 100 (FIGS. 1A and 1B), one or more of the gate contacts 135 may individually have a relatively larger horizontal area.

FIG. 3A is a simplified, top-down view of a microelectronic device structure 300, in accordance with additional embodiments (e.g., a third embodiment) of the disclosure. The microelectronic device structure 300 may be similar to the microelectronic device structure 100 previously described with reference to FIGS. 1A and 1B, except that, for example, the microelectronic device structure 300 may have at least one different annular shape for various features of a transistor 301 thereof than that of the transistor 101 (FIGS. 1A and 1B) of the microelectronic device structure 100. For example, as described in further detail below, the transistor 301 may have at least some features individually having a hexagonal annular shape. The microelectronic device structure 300 may also exhibit different configurations of one or more of source contact(s) 315, drain contact(s) 355, and gate contact(s) 335 thereof, as desired (and described in further detail below with respect to the source contact(s) 315, without limitation). FIG. 3B is a magnified, top-down view of a portion of the microelectronic device structure 300 shown in FIG. 3A, within the dashed box 3B depicted in FIG. 3A.

Referring to FIG. 3A, a drain 350 of the transistor 301 may have a hexagonal horizontal shape of an external drain perimeter thereof (corresponding to the external drain perimeter 159 (FIG. 1B)). A gate 330 of the transistor 301 horizontally circumscribing the drain 350 may have an inner gate perimeter (corresponding to the inner gate perimeter 131 (FIG. 1B)) and an outer gate perimeter (corresponding to the outer gate perimeter 139 (FIG. 1B)) respectively having a hexagonal horizontal shape. A source 310 of the transistor 301 horizontally circumscribing the gate 330 (and the channel thereunder) may be an internal source perimeter (corresponding to the internal source perimeter 111 (FIG. 1B)) having a hexagonal horizontal shape. A channel (equivalent to the channel 160 previously described with reference to FIGS. 1A and 1B) of the transistor 301, vertically underlying the gate 330 and horizontally interposed between the drain 350 and the source 310, may have an inner channel perimeter and an outer channel perimeter respectively having a hexagonal horizontal shape. The hexagonal shapes of the aforementioned perimeters of the different features (e.g., the source 310, the drain 350, the gate 330, the channel) of the transistor 301 may individually (and, optionally, collectively) be a regular shape (e.g., six (6) sides of equal dimension, and internal angles equal in measure) or an irregular shape (e.g., six (6) sides, but some sides are not of equal dimension, and/or some internal angles are not equal in measure).

The hexagonal annular shape of the gate 330 of the transistor 301 may facilitate a gate length that is relatively more uniform than that of the gate 130 of the transistor 101 previously described with reference to FIGS. 1A and 1B, particularly at horizontal corners of the gate 330. Referring to FIG. 3B, at a horizontal corner of gate 330, gate 330 may vary in gate length between a minimum gate length 332 between opposing, parallel-oriented peripheral boundaries of the source 310 and the drain 350 and a maximum gate length 338 at the corners of the gate 330. The increased number of sides of the gate 330 relative to the gate 130 (FIG. 1A) may enhance gate length uniformity (e.g., may reduce the difference between the maximum gate length 338 and the minimum gate length 332) at the horizontal corners of the gate 330 as compared to that of the gate 130 (FIG. 1A). The hexagonal annular shape of the gate 330 may have a smaller maximum gate length 338 compared to that of the rectangular annular shape of the gate 130 (FIG. 1A).

Referring collectively to FIGS. 3A and 3B, a relatively more uniform gate length of the gate 330 (and a correspondingly relatively more uniform length of the underlying channel) of the transistor 301 may facilitate a relatively more efficient flow of electrons from the source 310 to the drain 350 by promoting electron flow across relatively more sections of the outer gate perimeter of the gate 330 (rather than favoring certain sections of the outer gate perimeter of the gate 330, as may otherwise result from magnetic flux produced by relatively more non-uniform gate lengths). A relatively more uniform gate length permits a relatively more efficient ratio of the source overlap region 320 to the drain overlap region 340. More uniform electron flow from the internal source perimeter (corresponding to the internal source perimeter 111 (FIG. 1B)) of the source 310, through the channel (corresponding to the channel 160 (FIG. 1B)), and to the external drain perimeter (corresponding to the external drain perimeter 159 (FIG. 1B)) of the transistor 301 may effectuate electron flow closer to an ideal distribution wherein the entire internal source perimeter is utilized to an equal degree. The relatively uniform gate length of the gate 330 may permit a BUS system to more effectively drive a load of an output node due to a lower capacitance of the drain overlap region 340.

As shown in FIG. 3A, the microelectronic device structure 300 may include six (6) source contacts 315, wherein each of the six (6) source contacts 315 contacts a respective portion of the source 310 horizontally neighboring one of the six (6) outer sidewalls of the gate 330. An individual source contact 315 may horizontally extend along the horizontal dimension of a linear portion of the internal source perimeter (corresponding to the internal source perimeter 111 (FIG. 1B)) of the transistor 301. In additional embodiments, the microelectronic device structure 300 includes a different quantity (e.g., greater than six (6), less than six (6)) and/or arrangement (e.g., horizontal positioning) of the source contacts 315. Each of the source contacts 315 may exhibit substantially a same horizontal area as each other of the source contacts 315, or at least one of the source contacts 315 may exhibit a different horizontal area than at least one other of the source contacts 315.

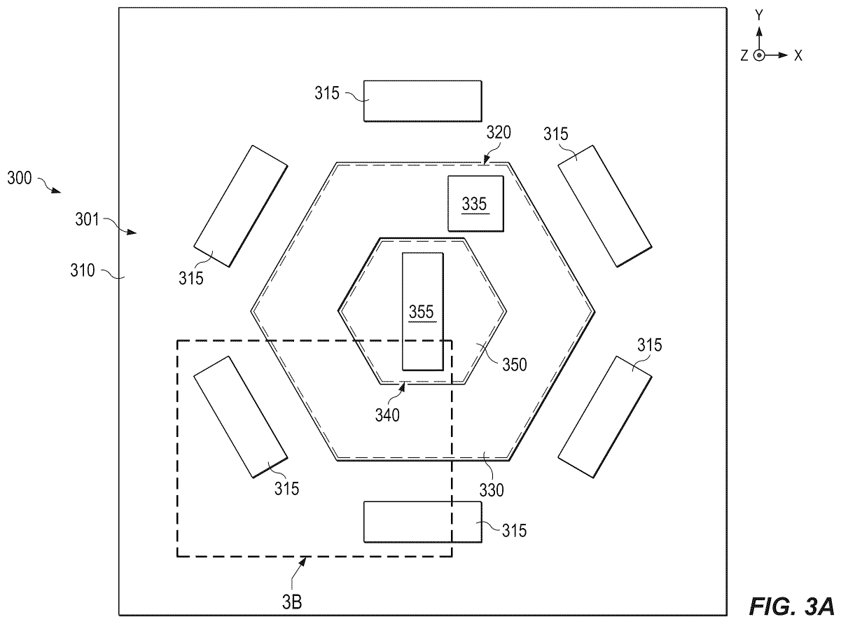

FIG. 4 is a simplified, top-down view of a microelectronic device structure 400, in accordance with additional embodiments (e.g., a fourth embodiment) of the disclosure. The microelectronic device structure 400 may be similar to the microelectronic device structure 100 previously described with reference to FIGS. 1A and 1B, except that, similar to the microelectronic device structure 300 (FIGS. 3A and 3B), the microelectronic device structure 400 may have at least one different annular shape for various features of a transistor 401 thereof than that of the transistor 101 (FIGS. 1A and 1B) of the microelectronic device structure 100. For example, as described in further detail below, the transistor 401 may have at least some features individually having an octagonal annular shape. The microelectronic device structure 400 may also exhibit different configurations of one or more of source contact(s) 415, drain contact(s) 455, and gate contact(s) 435 thereof, as desired (and described in further detail below with respect to the source contact(s) 415, without limitation).

A drain 450 of the transistor 401 may have an external drain perimeter (corresponding to the external drain perimeter 159 (FIG. 1B)) having an octagonal horizontal shape. A gate 430 of the transistor 401 horizontally circumscribing the drain 450 may have an inner gate perimeter (corresponding to the inner gate perimeter 131 (FIG. 1B)) and an outer gate perimeter (corresponding to the outer gate perimeter 139 (FIG. 1B)) respectively having an octagonal horizontal shape. A source 410 of the transistor 401 horizontally circumscribing the gate 430 (and the channel thereunder) may have an internal source perimeter (corresponding to the internal source perimeter 111 (FIG. 1B)) having an octagonal horizontal shape. A channel (equivalent to the channel 160 previously described with reference to FIGS. 1A and 1B) of the transistor 401, vertically underlying the gate 430 and horizontally interposed between the drain 450 and the source 410, may have an inner channel perimeter and an outer channel perimeter respectively having an octagonal horizontal shape. The octagonal shapes of the aforementioned perimeters of the different features (e.g., the source 410, the drain 450, the gate 430, the channel) of the transistor 401 may individually (and, optionally, collectively) be a regular shape (e.g., six (6) sides of equal dimension, and internal angles equal in measure) or an irregular shape (e.g., six (6) sides, but some sides are not of equal dimension, and/or some internal angles are not equal in measure).

The gate 430 of the transistor 401 may have a maximum gate length 438 and a minimum gate length 432. Compared to the maximum gate length 338 of the gate 330 of the transistor 301 described with reference to FIG. 3, the maximum gate length 438 may be relatively shorter. The minimum gate length 432 of the gate 430 may be the same as or different than the minimum gate length 332 of the gate 330 of the transistor 301 described with reference to FIG. 3.

The octagonal annular shape of the gate 430 may be advantageous for various reasons, including material limitations and spatial considerations. For example, the octagonal annular shape of the gate 430 may further enhance gate length uniformity (e.g., particularly at corners thereof) relative to other configurations, and/or may provide spatial benefits for various microelectronic device designs having certain dimensional limitations.

As shown in FIG. 4, the microelectronic device structure 400 may include six (6) source contacts 415, wherein each of the six (6) source contacts 415 contacts a respective portion of the source 410 horizontally neighboring one of the eight (8) outer sidewalls of the gate 430. An individual source contact 415 may horizontally extend along the horizontal dimension of a linear portion of the internal source perimeter (corresponding to the internal source perimeter 111 (FIG. 1B)) of the transistor 401. In additional embodiments, the microelectronic device structure 400 includes a different quantity (e.g., greater than six (6), less than six (6)) and/or arrangement (e.g., horizontal positioning) of the source contacts 415. For example, the microelectronic device structure 400 may include eight (8) source contacts 415, wherein each of the eight (8) source contacts 415 contacts a respective portion of the source 410 horizontally neighboring one of the eight (8) outer sidewalls of the gate 430. Each of the source contacts 415 may exhibit substantially a same horizontal area as each other of the source contacts 415, or at least one of the source contacts 415 may exhibit a different horizontal area than at least one other of the source contacts 415.

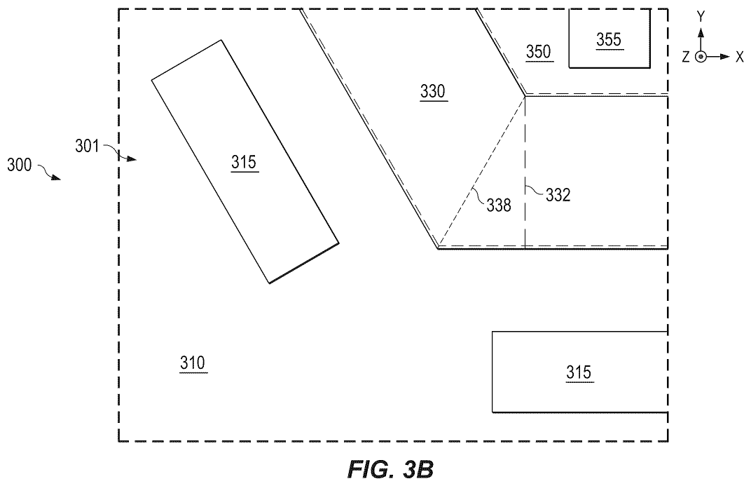

FIG. 5 is a simplified, top-down view of a microelectronic device structure 500, in accordance with additional embodiments (e.g., a fifth embodiment) of the disclosure. The microelectronic device structure 500 may be similar to the microelectronic device structure 100 previously described with reference to FIGS. 1A and 1B, except that, similar to the microelectronic device structure 300 (FIGS. 3A and 3B) and the microelectronic device structure 400 (FIG. 4), the microelectronic device structure 500 may have at least one different annular shape for various features of a transistor 501 thereof than that of the transistor 101 (FIGS. 1A and 1B) of the microelectronic device structure 100. For example, as described in further detail below, the transistor 501 may have at least some features individually having a closed-curve annular shape (e.g., a circular annular shape, an ovular annular shape). The microelectronic device structure 500 may also exhibit different configurations of one or more of source contact(s) 515, drain contact(s) 555, and gate contact(s) 535 thereof, as desired.

A drain 550 of the transistor 501 may have an external drain perimeter (corresponding to the external drain perimeter 159 (FIG. 1B)) having a closed-curve horizontal shape (e.g., a circular shape, an ovular shape). A gate 530 of the transistor 501 horizontally circumscribing the drain 550 may have an inner gate perimeter (corresponding to the inner gate perimeter 131 (FIG. 1B)) and an outer gate perimeter (corresponding to the outer gate perimeter 139 (FIG. 1B)) respectively having a closed-curve horizontal shape (e.g., a circular shape, an ovular shape). A source 510 of the transistor 501 horizontally circumscribing the gate 530 (and the channel thereunder) may have an internal source perimeter (corresponding to the internal source perimeter 111 (FIG. 1B)) having a closed-curve horizontal shape (e.g., a circular shape, an ovular shape). A channel (equivalent to the channel 160 previously described with reference to FIGS. 1A and 1B) of the transistor 501, vertically underlying the gate 530 and horizontally interposed between the drain 550 and the source 510, may have an inner channel perimeter and an outer channel perimeter respectively having a closed-curve horizontal shape (e.g., a circular shape, an ovular shape).

In some embodiments, the closed-curve annular shape of the gate 530 of the transistor 501 further enhances gate length uniformity of the gate 530 relative to other configurations. For example, if the gate 530 has a substantially circular annular shape, the gate length thereof may be relatively more uniform as compared to gate configurations having non-closed-curve shapes (e.g., including horizontal corners imparting differences between minimum gate lengths and maximum gate lengths) or a different closed-curve annular shape (e.g., an ovular annular shape).

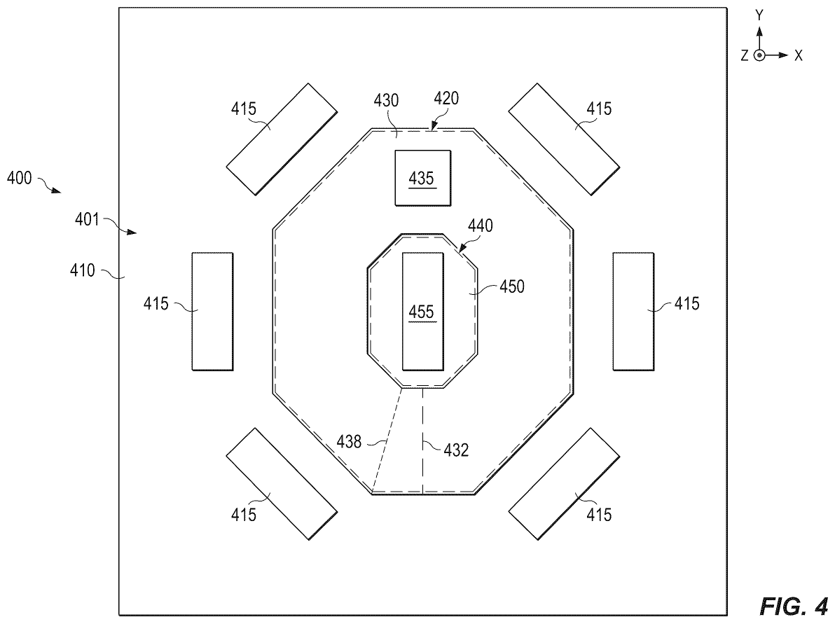

FIG. 6 is a simplified, top-down view of a microelectronic device structure 600, in accordance with additional embodiments (e.g., a sixth embodiment) of the disclosure. The microelectronic device structure 600 may be similar to the microelectronic device structure 100 previously described with reference to FIGS. 1A and 1B, except that, similar to the microelectronic device structure 300 (FIGS. 3A and 3B), the microelectronic device structure 400 (FIG. 4), the microelectronic device structure 500 (FIG. 5), and the microelectronic device structure 600 may have at least one different shape for one or more features of a transistor 501 thereof than that of the transistor 101 (FIGS. 1A and 1B) of the microelectronic device structure 100. For example, as described in further detail below, the transistor 601 may have at least some features individually having a partially annular shape. For example, a source 610 of the transistor 601 only partially horizontally circumscribes each of the gate 630, the drain 650, and the channel (corresponding to the channel 160 previously described with reference to FIG. 1B) of the transistor 601. The partially annular shape of the source 610 may accommodate a different annular shape of the gate 630 that includes an extension portion 633 configured to receive gate contact(s) 635 thereon. The microelectronic device structure 600 may also exhibit different configurations of one or more of source contact(s) 615, drain contact(s) 655, and the gate contact(s) 635 thereof, as desired (and described in further detail below with respect to the gate contact(s) 635, without limitation).

A drain 650 of the transistor 601 may have an external drain perimeter (corresponding to the external drain perimeter 159 (FIG. 1B)) having a rectangular horizontal shape.

The gate 630 of the transistor 601 horizontally circumscribing the drain 650 may have an inner gate perimeter (corresponding to the inner gate perimeter 131 (FIG. 1B)) having a rectangular horizontal shape, and an outer gate perimeter (corresponding to the outer gate perimeter 139 (FIG. 1B)) having an irregular horizontal shape that accommodates the extension portion 633 at one of the horizontal corners of the gate 630. The extension portion 633 of the gate 630 may, for example, have a generally rectangular shape that is unitary with an additional portion of the gate 630 having a generally rectangular annular shape. The extension portion 633 of the gate 630 may be horizontally sized to receive a gate contact 635 having one or more horizontal dimensions (e.g., in the X-direction, in the Y-direction) relatively greater than corresponding horizontal dimensions of additional portions of the gate 630 horizontally extending from and between the source 610 and the drain 650.

The source 610 of the transistor 601 partially horizontally circumscribing the gate 630 (and the channel thereunder) may have an internal source perimeter (corresponding to the internal source perimeter 111 (FIG. 1B)) having an irregular horizontal shape (e.g., a C-shape, a G-shape). Less than all of the sides of the extension portion 633 of the gate 630 may be horizontally surrounded by the source 610. For example, two (2) sides of the extension portion 633 most horizontally proximate to the inner gate perimeter of the gate 630 may be surrounded by the source 610, while two (2) additional sides of the extension portion 633 relatively more horizontally distal from the inner gate perimeter of the gate 630 may not be surrounded by the source 610. As a result, the inner gate perimeter of the gate 630 (e.g., including each of four (4) horizontal sides thereof) may be substantially horizontally surrounded by the source 610, except at a horizontal corner thereof most proximate to the extension portion 633.

A channel (equivalent to the channel 160 previously described with reference to FIGS. 1A and 1B) of the transistor 601, vertically underlying the gate 630 and horizontally interposed between the drain 650 and the source 610, may have an inner channel perimeter having a rectangular horizontal shape, and an outer channel perimeter having an irregular horizontal shape (e.g., a C-shape, a G-shape) that complements the irregular horizontal shape (e.g., a C-shape, a G-shape) of the internal source perimeter of the source 610. The channel may not substantially horizontally extend into a horizontal area of the extension portion 633 of the gate 630. An isolation material 637 (e.g., insulative material) may be positioned at a vertical elevation (e.g., in the Z-direction) of the channel, the source 610, and the drain 650 and may be present within and may substantially horizontally extend across at least a horizontal area of the extension portion 633 of the gate 630.

As shown in FIG. 6 and previously discussed herein, the microelectronic device structure 600 may include gate contact(s) 635 within a horizontal area of and in contact with the extension portion 633 of the gate 630. In some embodiments, a single (e.g., only one) gate contact 635 is provided with the horizontal area of the extension portion 633, and has a horizontal center substantially aligned with a horizontal center of the extension portion 633. In additional embodiments, the microelectronic device structure 600 includes a different quantity (e.g., greater than one (1)) and/or arrangement (e.g., horizontal positioning) of the gate contact(s) 635. For example, the microelectronic device structure 600 may include multiple gate contacts 635 within a horizontal area of and in contact with the extension portion 633 of the gate 630. Each of the gate contacts 635 may exhibit substantially a same horizontal area as each other of the gate contacts 635, or at least one of the gate contacts 635 may exhibit a different horizontal area than at least one other of the gate contacts 635.

Thus, in accordance with embodiments of the disclosure, a transistor includes a drain, a channel substantially horizontally circumscribing the drain, a source at least partially horizontally circumscribing the channel, a gate vertically overlying and substantially covering a horizontal area of the channel, and a gate dielectric material vertically interposed between and horizontally overlapping the gate and the channel. The gate includes portions partially horizontally overlapping the source and the drain.

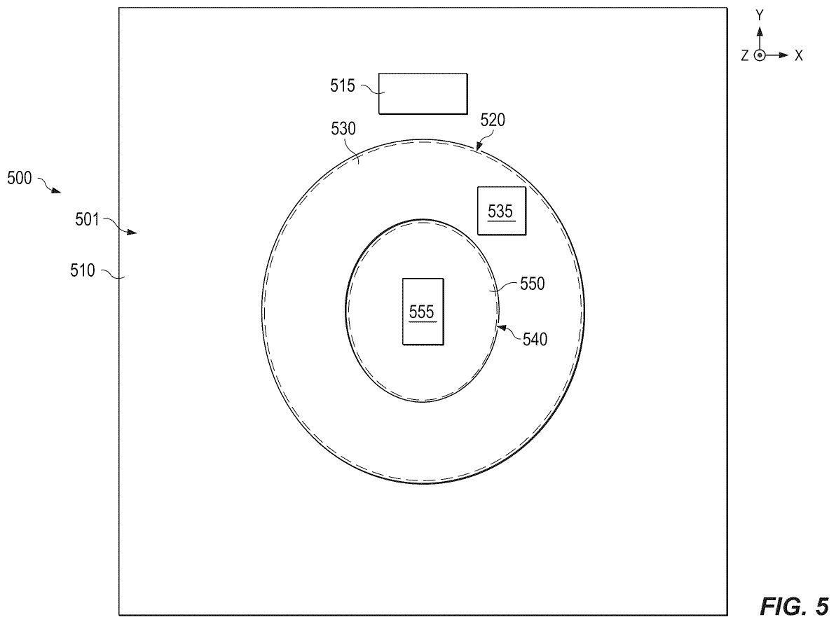

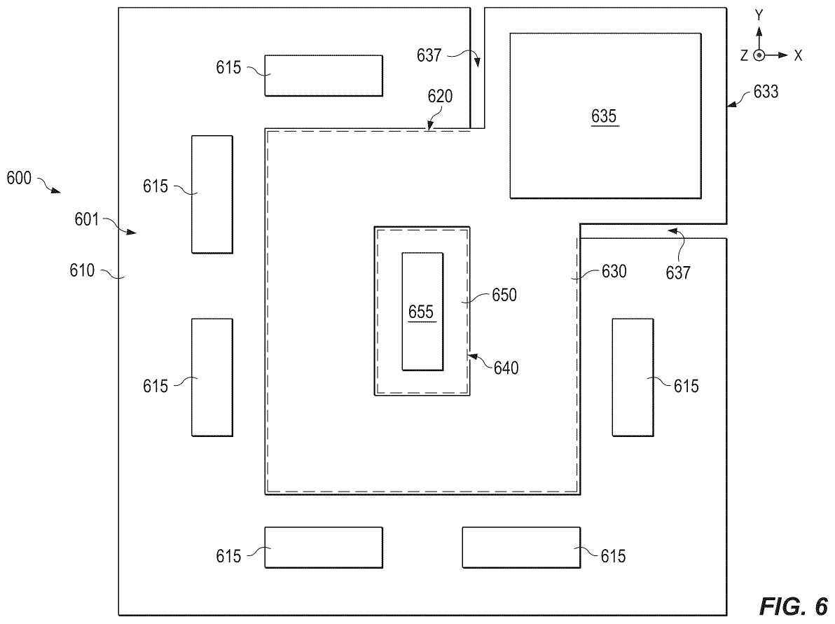

While FIGS. 1A through 6 illustrate microelectronic device structures (e.g., the microelectronic device structures 100, 200, 300, 400, 500, 600) including one (1) transistor (e.g., the transistors 101, 201, 301, 401, 501, 601), microelectronic device structures in accordance with embodiments of the disclosure may individually include multiple (e.g., more than one) transistors of the disclosure operatively associated with one another and additional features of a microelectronic device of the disclosure in desirable ways. All of the transistors may have substantially the same geometric configuration (e.g., may individually have a geometric configuration corresponding to that of one of the transistors 101, 201, 301, 401, 501, 601); or one or more of the transistors may have a different geometric configuration than one or more others of the transistors (e.g., one of the transistors may have a geometric configuration corresponding to that of one of the transistors 101, 201, 301, 401, 501, 601; and an additional one of the transistors may have a geometric configuration corresponding to that of different ones of the transistors 101, 201, 301, 401, 501, 601). At least one of the transistors may be arranged (e.g., coupled) in parallel with at least one other of the transistors; at least one of the transistors may be arranged (e.g., coupled) in series with at least one other of the transistors; or a combination thereof. Non-limiting examples of microelectronic device structures of the disclosure including multiple transistors of the disclosure are described in further detail below with reference to FIGS. 7 and 8.

FIG. 7 is a simplified, top-down view of a microelectronic device structure 700, in accordance with additional embodiments (e.g., a seventh embodiment) of the disclosure. The microelectronic device structure 700 includes multiple (e.g., four (4)) transistors 701. The transistors 701 are arranged (e.g., coupled) in parallel with one another within the microelectronic device structure 700. The transistors 701 respectively have a configuration similar to that of the transistor 601 previously described herein with reference to FIG. 6, except that gates 730 of the transistors 701 may share the same extension portion 733 (and, hence, the same gate contact(s) 735) with one another. For example, the shared extension portion 733 may be positioned in a horizontally central (i.e., in the X-direction, in the Y-direction) position relative to four (4) of the transistors 701, and may be unitary with four (4) different horizontal corners of gates 730 of the transistors 701. Accordingly, the shared extension portion 733 and the additional portions of the gates 730 for the four (4) transistors 701 may effectively form a single gate 730 shared by each of the four (4) transistors 701. The microelectronic device structure 700 exhibits similar configurations of the source contacts 715, the drain contacts 755, and the gate contact 735 operantly associated with respective ones of the transistors 701 thereof to those previously described herein, respectively, for the source contacts 615 (FIG. 6), the drain contact 655 (FIG. 6), and the gate contact 635 (FIG. 6) of the microelectronic device structure 600 (FIG. 6), as modified (e.g., horizontally positioned, horizontally oriented) to accommodate the configurations of the transistors 701 relative to one another in the manner shown in FIG. 7. In some embodiments, the source contacts 715 of the microelectronic device structure 700 are coupled with one another; and the drain contacts 755 of the microelectronic device structure 700 are coupled with one another.

FIG. 8 is a simplified, top-down view of a microelectronic device structure 800, in accordance with additional embodiments (e.g., an eighth embodiment) of the disclosure. The microelectronic device structure 800 includes multiple (e.g., three (3)) transistors 801. The transistors 801 all may be arranged (e.g., coupled) in parallel with one another within the microelectronic device structure 800; the transistors 801 all may be arranged (e.g., coupled) in series with one another within the microelectronic device structure 800; or some of the transistors 801 may be arranged (e.g., coupled) in parallel with one another within the microelectronic device structure 800 and some others of the transistors 801 may be arranged (e.g., coupled) in series with one another within the microelectronic device structure 800. The transistors 801 respectively have a configuration similar to that of the transistor 301 previously described herein with reference to FIGS. 3A and 3B. The microelectronic device structure 800 exhibits similar configurations of the source contacts 815, the drain contacts 855, and the gate contact 835 operantly associated with respective ones of the transistors 801 thereof to those previously described herein, respectively, for the source contacts 315 (FIG. 3A), the drain contact 355 (FIG. 3A), and the gate contact 335 (FIG. 3A) of the microelectronic device structure 300 (FIG. 3A), as modified (e.g., horizontally positioned, horizontally oriented) to accommodate the configurations of the transistors 801 relative to one another in the manner shown in FIG. 8. In some embodiments, the source contacts 815 of the microelectronic device structure 800 are coupled with one another; the drain contacts 855 of the microelectronic device structure 800 are coupled with one another; and the gate contacts 835 of the microelectronic device structure 800 are coupled with one another. In additional embodiments, some of the source contacts 815 are not coupled to some others of the source contacts 815; some of the drain contacts 855 are not coupled to some others of the drain contacts 855; and/or some of the gate contacts 835 are not coupled to some others of the gate contacts 835.

While FIGS. 7 and 8 show the microelectronic device structure 700 (FIG. 7) and the microelectronic device structure 800 (FIG. 8) as including transistor configurations of the disclosure, it will be understood that microelectronic device structures according to additional embodiments of the disclosure may include one or more transistors of the disclosure (e.g., one or more of the transistors 101, 201, 301, 401, 501, 601 previously described herein with reference to FIGS. 1A through 6) in combination with one or more different transistor configurations (e.g., one or more conventional transistor configurations, one or more future transistor configurations).

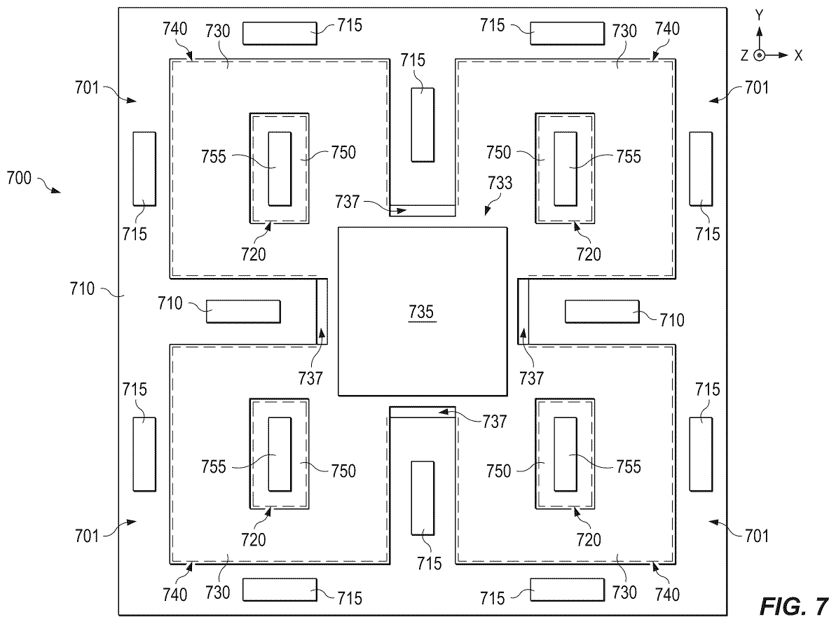

Microelectronic device structures (e.g., one or more of the microelectronic device structures 100, 200, 300, 400, 500, 600, 700, 800 previously described with reference to FIGS. 1A through 8) according to embodiments of the disclosure (including the transistors thereof) may be included in various control logic devices (e.g., inverters, such as complementary metal-oxide-semiconductor (CMOS) inverters; two-input NAND gates; balanced CMOS inverters; balanced CMOS transmission pass gates; balanced two-input NAND gates) of the disclosure. By way of non-limiting example, FIG. 9 is a simplified diagram of an inverter 903 (e.g., a CMOS inverter), in accordance with embodiments of the disclosure. FIG. 9 depicts simplified, top-down views of two (2) transistors 901 (e.g., a first transistor 901A, and a second transistor 901B) of the disclosure, employed in combination with various conductive routing structures (described in further detail below) to form the inverter 903.

As shown in FIG. 9, each of the transistors 901 of the inverter 903 may have a configuration similar to that of the transistor 101 previously described with reference to FIGS. 1A and 1B. However, the first transistor 901A may be configured as a PMOS transistor, and the second transistor 901B may be configured as an NMOS transistor. The first transistor 901A may include a source 910 and a drain 950 that are each P-type doped, as well as a channel (e.g., vertically underlying the gate 930 thereof, and corresponding to the channel 160 of the transistor 101 previously described with reference to FIGS. 1A and 1B) that is N-type doped. The second transistor 901B may include a source 910 and a drain 950 that are each N-type doped, as well as a channel (e.g., vertically underlying the gate 930 thereof, and corresponding to the channel 160 of the transistor 101 previously described with reference to FIGS. 1A and 1B) that is P-type doped.

The inverter 903 also includes a positive supply voltage (V_{dd}) structure 905 coupled to the source 910 of the first transistor 901A (PMOS transistor); a negative supply voltage (Vₛₛ) structure 907 coupled to the source 910 of the second transistor 901B (NMOS transistor); an output structure 909 coupled to the drain 950 (P-type drain) of the first transistor 901A and drain 950 (N-type drain) of the second transistor 901B; and an input structure 913 coupled to the gates 930 of the first transistor 901A and the second transistor 901B.

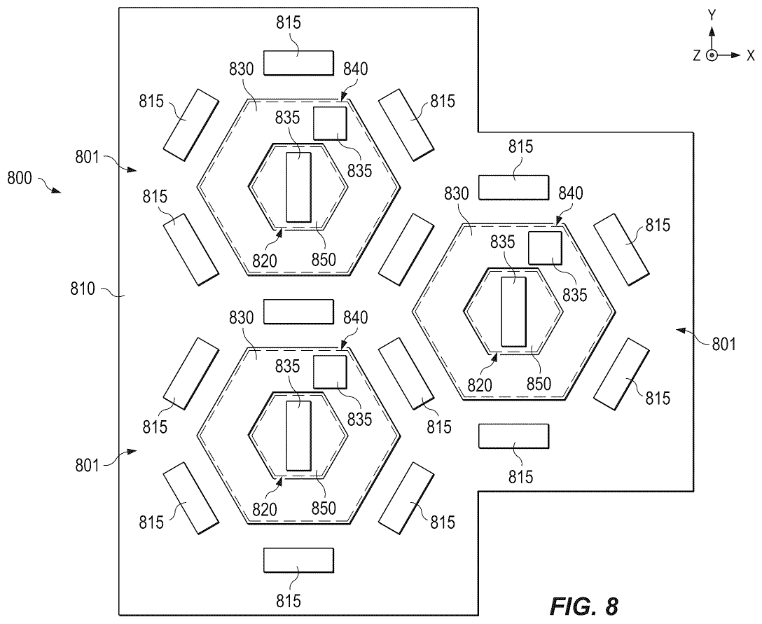

Microelectronic device structures (e.g., microelectronic device structures 100, 200, 300, 400, 500, 600, 700, 800 previously described with reference to FIGS. 1A through 8) and control logic devices (e.g., the inverter 903 previously described with reference to FIG. 9) of the disclosure may be included in microelectronic devices (e.g., memory devices, such as volatile memory devices and/or non-volatile memory devices) of the disclosure. As a non-limiting example, FIG. 10 illustrates a functional block diagram of a memory device 1000 (e.g., a volatile memory device, such as a dynamic random access memory (DRAM) device), in accordance with an embodiment of the disclosure. The memory device 1000 may include, for example, an embodiment of one or more of a microelectronic device structure, a transistor, a control logic device previously described herein with reference to one or more of FIGS. 1A through 9. As shown in FIG. 10, the memory device 1000 may include memory cells 1002, digit lines 1004, word lines 1006, a row decoder 1008, a column decoder 1010, a memory controller 1012, a sense device 1014, and an input/output device 1016. Microelectronic device structures, transistors, control logic devices of the disclosure, as previously described herein with reference to one or more of FIGS. 1A through 9 may, for example, be employed in any of the row decoder 1008, the column decoder 1010, the memory controller 1012, the sense device 1014, and the input/output device 1016 of the memory device 1000, without limitation.

The memory cells 1002 of the memory device 1000 are programmable to at least two different logic states (e.g., logic 0 and logic 1). Each memory cell 1002 may individually include a storage node device (e.g., a capacitor) and an access device (e.g., a transistor). The capacitor stores a charge representative of the programmable logic state (e.g., a charged capacitor may represent a first logic state, such as a logic 1; and an uncharged capacitor may represent a second logic state, such as a logic 0) of the memory cell 1002. The transistor grants access to the capacitor upon application (e.g., by way of one of the word lines 1006) of a minimum threshold voltage to a semiconductive channel thereof for operations (e.g., reading, writing, rewriting) on the capacitor. In some embodiments, the access device of at least one of the memory cells 1002 has a configuration corresponding to one of the transistors of the disclosure (e.g., one of the transistors 101, 201, 301, 401, 501, 601) previously described herein with reference to one or more of FIGS. 1A through 6.

The digit lines 1004 are connected to the storage node devices of the memory cells 1002 by way of the access devices of the memory cells 1002. The word lines 1006 extend perpendicular to the digit lines 1004 and serve as gates of the access devices of the memory cells 1002. Operations may be performed on the memory cells 1002 by activating appropriate digit lines 1004 and word lines 1006. Activating a digit line 1004 or a word line 1006 may include applying a voltage potential to the digit line 1004 or the word line 1006. Each column of memory cells 1002 may individually be connected to one of the digit lines 1004, and each row of the memory cells 1002 may individually be connected to one of the word lines 1006. Individual memory cells 1002 may be addressed and accessed through the intersections (e.g., cross points) of the digit lines 1004 and the word lines 1006.

The memory controller 1012 may control the operations of memory cells 1002 through various components, including the row decoder 1008, the column decoder 1010, and the sense device 1014 (e.g., local I/O device). The memory controller 1012 may generate row address signals that are directed to the row decoder 1008 to activate (e.g., apply a voltage potential to) predetermined word lines 1006, and may generate column address signals that are directed to the column decoder 1010 to activate (e.g., apply a voltage potential to) predetermined digit lines 1004. The sense device 1014 may include sense amplifiers configured and operated to receive digit line inputs from the digit lines selected by the column decoder 1010 and to generate digital data values during read operations. The memory controller 1012 may also generate and control various voltage potentials employed during the operation of the memory device 1000. In general, the amplitude, shape, and/or duration of an applied voltage may be adjusted (e.g., varied), and may be different for various operations of the memory device 1000.

During use and operation of the memory device 1000, after being accessed, a memory cell 1002 may be read (e.g., sensed) by the sense device 1014. The sense device 1014 may compare a signal (e.g., a voltage) of an appropriate digit line 1004 to a reference signal in order to determine the logic state of the memory cell 1002. If, for example, the digit line 1004 has a higher voltage than the reference voltage, the sense device 1014 may determine that the stored logic state of the memory cell 1002 is a logic 1, and vice versa. The sense device 1014 may include transistors and amplifiers to detect and amplify a difference in the signals (commonly referred to in the art as “latching”). The detected logic state of a memory cell 1002 may be output through the column decoder 1010 to the input/output device 1016. In addition, a memory cell 1002 may be set (e.g., written) by similarly activating an appropriate word line 1006 and an appropriate digit line 1004 of the memory device 1000. By controlling the digit line 1004 while the word line 1006 is activated, the memory cell 1002 may be set (e.g., a logic value may be stored in the memory cell 1002). The column decoder 1010 may accept data from the input/output device 1016 to be written to the memory cells 1002. Furthermore, a memory cell 1002 may also be refreshed (e.g., recharged) by reading the memory cell 1002. The read operation will place the contents of the memory cell 1002 on the appropriate digit line 1004, which is then pulled up to full level (e.g., full charge or discharge) by the sense device 1014. When the word line 1006 associated with the memory cell 1002 is deactivated, all of memory cells 1002 in the row associated with the word line 1006 are restored to full charge or discharge.

Thus, in accordance with embodiments of the disclosure, a microelectronic device includes transistors respectively including a drain; an annular channel substantially horizontally surrounding the drain; an annular source substantially horizontally surrounding the drain; an annular gate vertically overlying and horizontally portions of each of the drain, the annular channel, and the annular source; and gate dielectric material vertically interposed between and substantially covering a lower surface of the annular gate and an upper surface of the annular channel.

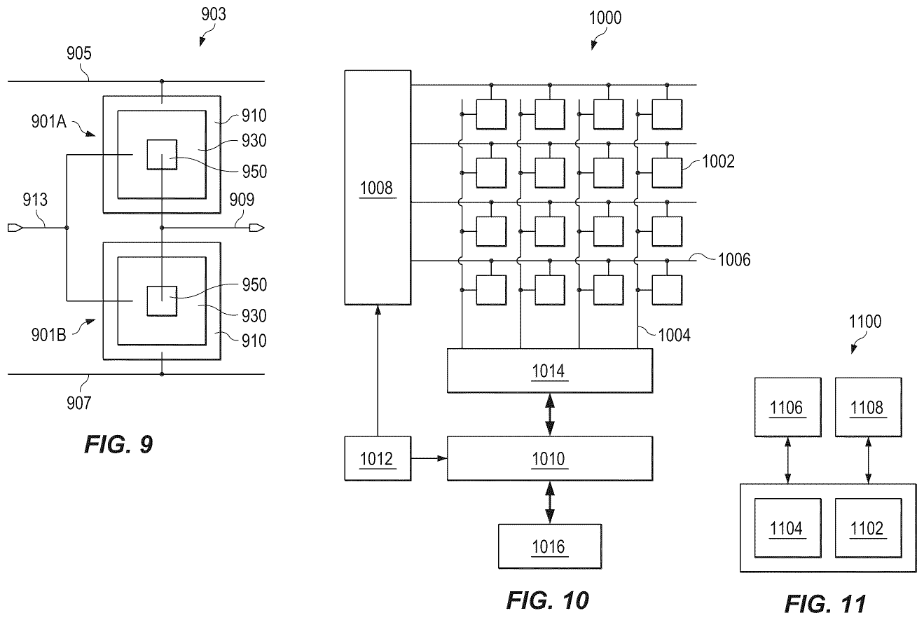

Microelectronic devices (e.g., the memory device 1000 previously described with reference to FIG. 10), microelectronic device structures (e.g., microelectronic device structures 100, 200, 300, 400, 500, 600, 700, 800 previously described with reference to FIGS. 1A through 8), and/or control logic devices (e.g., the inverter 903 previously described with reference to FIG. 9) in accordance with embodiments of the disclosure may be used in embodiments of electronic systems of the disclosure. For example, FIG. 11 is a block diagram of an illustrative electronic system 1100 according to embodiments of disclosure. The electronic system 1100 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc.

The electronic system 1100 includes at least one memory device 1102. The memory device 1102 may include, for example, one or more of a microelectronic device structure (e.g., one or more of the microelectronic device structures 100, 200, 300, 400, 500, 600, 700, 800 previously described with reference to FIGS. 1A through 8) and a control logic device (e.g., the inverter 903 previously described with reference to FIG. 9) previously described herein.

The electronic system 1100 may further include at least one electronic signal processor device 1104 (often referred to as a “microprocessor”). The electronic signal processor device 1104 may, optionally, include one or more of a microelectronic device, a microelectronic device structure (e.g., one or more of the microelectronic device structures 100, 200, 300, 400, 500, 600, 700, 800 previously described with reference to FIGS. 1A through 8), and a control logic device (e.g., the inverter 903 previously described with reference to FIG. 9) previously described herein.

While the memory device 1102 and the electronic signal processor device 1104 are depicted as two (2) separate devices in FIG. 11, in additional embodiments, a single (e.g., only one) memory/processor device having the functionalities of the memory device 1102 and the electronic signal processor device 1104 is included in the electronic system 1100. In such embodiments, the memory/processor device may include one or more of a microelectronic device (e.g., the memory device 1000 previously described with reference to FIG. 10), a microelectronic device structure (e.g., one or more of the microelectronic device structures 100, 200, 300, 400, 500, 600, 700, 800 previously described with reference to FIGS. 1A through 8), and a control logic device (e.g., the inverter 903 previously described with reference to FIG. 9) previously described herein.

The electronic system 1100 may further include one or more input devices 1106 for inputting information into the electronic system 1100 by a user, such as, for example, a mouse or other pointing device, a keyboard, a touchpad, a button, or a control panel. The electronic system 1100 may further include one or more output devices 1108 for outputting information (e.g., visual or audio output) to a user such as, for example, a monitor, a display, a printer, an audio output jack, a speaker, etc. In some embodiments, the input device 1106 and the output device 1108 may comprise a single touchscreen device that can be used both to input information to the electronic system 1100 and to output visual information to a user. The input device 1106 and the output device 1108 may communicate electrically with one or more of the memory device 1102 and the electronic signal processor device 1104.

Thus, in accordance with embodiments of the disclosure, an electronic system includes an input device, an output device, a processor device operably coupled to the input device and the output device, and a memory device operably coupled to the processor device and including transistors. The transistors individually include a drain, a channel, a source, a gate, and a gate dielectric material. The drain has an outer drain perimeter. The channel is at a vertical position of the drain and has an inner channel perimeter substantially horizontally surrounding the outer drain perimeter of the drain. The source is at the vertical position of the drain and has an inner source perimeter substantially horizontally surrounding an outer channel perimeter of the channel. The gate is vertically above the vertical position of the drain and has an annular shape that overlaps each of the outer drain perimeter of the drain and the inner source perimeter of the source. The gate dielectric material vertically intervenes between the gate and the channel.

The structures, devices, and systems of the disclosure advantageously facilitate one or more of improved microelectronic device performance, reduced costs (e.g., manufacturing costs, material costs), increased miniaturization of components, and greater packaging density as compared to conventional structures, conventional devices, and conventional systems. The structures, devices, and systems of the disclosure may also improve scalability, efficiency, and simplicity as compared to conventional structures, conventional devices, and conventional systems.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalent. For example, elements and features disclosed in relation to one embodiment may be combined with elements and features disclosed in relation to other embodiments of the disclosure.

What is claimed is:

1. A transistor, comprising:
a drain;
a channel substantially horizontally circumscribing the drain;
a source at least partially horizontally circumscribing the channel;
a gate vertically overlying and substantially covering a horizontal area of the channel, the gate including portions partially horizontally overlapping the source and the drain; and
gate dielectric material vertically interposed between and horizontally overlapping the gate and the channel.

2. The transistor of claim 1, wherein the gate has an annular horizontal cross-sectional shape.

3. The transistor of claim 2, wherein the channel has an additional annular horizontal cross-sectional shape having a smaller horizontal area than that of the gate.

4. The transistor of claim 3, wherein the source has a further annular horizontal cross-sectional shape substantially horizontally circumscribing each of the channel and the gate.

5. The transistor of claim 1, wherein:
the drain has an external horizontal perimeter;
the source has an internal horizontal perimeter substantially horizontally surrounding the external horizontal perimeter of the drain; and
a ratio of a size of the external horizontal perimeter of the drain to an additional size of the internal horizontal perimeter of the source is within a range of from about 0.4 to about 0.8.

6. The transistor of claim 1, wherein:
the gate horizontally overlaps the source by a first distance; and
the gate horizontally overlaps the drain by a second distance substantially equal to the first distance.

7. The transistor of claim 1, wherein the gate comprises:
a rectangular inner horizontal perimeter; and
a rectangular outer horizontal perimeter.

8. The transistor of claim 1, wherein the gate comprises:
a rectangular inner horizontal perimeter; and
an irregular outer horizontal perimeter.

9. The transistor of claim 1, wherein the gate comprises:
a closed-curve inner horizontal perimeter; and
a closed-curve outer horizontal perimeter.

10. The transistor of claim 1, wherein the gate comprises:
a hexagonal inner horizontal perimeter; and
a hexagonal outer horizontal perimeter.

11. The transistor of claim 1, wherein the gate comprises:
an octagonal inner horizontal perimeter; and
an octagonal outer horizontal perimeter.

12. The transistor of claim 1, wherein the gate has substantially uniform gate length between horizontally opposing portions of an inner horizontal perimeter and an outer horizontal perimeter thereof.

13. A microelectronic device, comprising:
transistors respectively comprising:
a drain;
an annular channel substantially horizontally surrounding the drain;
an annular source substantially horizontally surrounding the drain;
an annular gate vertically overlying and horizontally portions of each of the drain, the annular channel, and the annular source; and
gate dielectric material vertically interposed between and substantially covering a lower surface of the annular gate and an upper surface of the annular channel.

14. The microelectronic device of claim 13, wherein a horizontally outer portion of the annular gate substantially continuously horizontally overlaps an entirety of an inner horizontal perimeter of the annular source.

15. The microelectronic device of claim 14, wherein a horizontally inner portion of the annular gate substantially continuously horizontally overlaps an entirety of an outer horizontal perimeter of the drain.

16. The microelectronic device of claim 13, wherein the annular gate has one of a rectangular annular shape, a hexagonal annular shape, an octagonal annular shape, a closed-curve annular shape, and an irregular annular shape.

17. The microelectronic device of claim 13, wherein the transistors comprise at least two transistors arranged in parallel with one another.

18. The microelectronic device of claim 13, wherein the transistors comprise at least two transistors arranged in series with one another.

19. An electronic system, comprising;
an input device;
an output device;
a processor device operably coupled to the input device and the output device; and
a memory device operably coupled to the processor device and comprising transistors individually comprising:
a drain having an outer drain perimeter;
a channel at a vertical position of the drain and having an inner channel perimeter substantially horizontally surrounding the outer drain perimeter of the drain;
a source at the vertical position of the drain and having an inner source perimeter substantially horizontally surrounding an outer channel perimeter of the channel;
a gate vertically above the vertical position of the drain and having an annular shape that overlaps each of the outer drain perimeter of the drain and the inner source perimeter of the source; and
gate dielectric material vertically intervening between the gate and the channel.

20. The electronic system of claim 19, wherein the memory device comprises a CMOS inverter comprising two of the transistors.
